(19) United States
(12) Patent Application Publication
(10) Pub. No.: US 2018/0175209 A1
(43) Pub. Date: Jun. 21, 2018

(54) SEMICONDUCTOR STRUCTURE INCLUDING ONE OR MORE NONVOLATILE MEMORY CELLS AND METHOD FOR THE FORMATION THEREOF

(71) Applicant: GLOBALFOUNDRIES Inc., Grand Cayman (KY)

(72) Inventors: Juergen Faul, Radebeul (DE); Frank Jakubowski, Dresden (DE)

(21) Appl. No.: 15/384,706

(22) Filed: Dec. 20, 2016

(51) Int. Cl. H01L 29/788; H01L 29/423; H01L 29/06; H01L 29/78; H01L 29/66; H01L 21/3105

(52) U.S. Cl. CPC H01L 29/7882; H01L 29/42328; H01L 21/3105; H01L 29/7838; H01L 29/66825; H01L 29/0649

(57) ABSTRACT

A semiconductor structure includes a support substrate including a semiconductor material, a buried insulation layer positioned above the support substrate, a semiconductor layer positioned above the buried insulation layer, the semiconductor layer having an upper surface and a lower surface, the lower surface being positioned on the buried insulation layer, and at least one nonvolatile memory cell. The nonvolatile memory cell includes a channel region, a front gate structure, a doped back gate region and a charge storage material. The channel region is located in the semiconductor layer. The front gate structure is located above the channel region and the upper surface of the semiconductor layer. The doped back gate region is located in the support substrate below the channel region. The charge storage material is embedded at least into a portion of the buried insulation layer between the channel region and the back gate region.

### BACKGROUND

### 1. Field of the Disclosure

Generally, the present disclosure relates to the field of integrated circuits, and, more particularly, to integrated circuits including nonvolatile memory devices.

### 2. Description of the Related Art

Nonvolatile memory such as, for example, flash memory may be used in various storage devices such as, for example, secure digital memory cards (SD cards), USB sticks, solid state drives (SSDs) and internal memory of various electronic devices such as, for example, mobile phones, tablet computers, media players, etc. Further applications of nonvolatile memory include embedded systems, wherein nonvolatile memory blocks including nonvolatile memory are provided in addition to logic devices and/or volatile memory devices, and wherein the nonvolatile memory devices and the logic devices and/or volatile memory devices are physically and electrically integrated on a single substrate, for example, a single monolithic silicon substrate. Devices that may be provided on the monolithic silicon substrate in addition to nonvolatile memory cells may include logic transistors, being field effect transistors that are provided in logic circuits and/or field effect transistors provided in volatile memory circuits such as static random access memory and/or dynamic random access memory. Embedded systems including nonvolatile memory find applications in various fields. For example, they may be used in automotive and internet-of-things applications. Integrating nonvolatile memory and logic circuitry and/or volatile memory on a single substrate may help to improve performance and reduce costs compared to solutions wherein nonvolatile memory and logic and/or volatile memory circuits are provided on separate substrates, for example, due to an elimination of input/output buffers, design flexibility, lower power consumption and/or system-on-a-chip capability.

Types of flash memory cell architectures that have been used in embedded systems include one transistor cells (1 T-cells) including a single gate, as well as split gate solutions such as a 1.5 transistor (1.5T) and 2 transistor (2T) cells. In such memory cells, bits of data stored in the memory cells may be represented by an amount of charge stored in a flash gate electrode that is surrounded by an electrically insulating material. Known flash memory cells may be formed in a substantially planar configuration on a wafer surface, wherein a number of additional manufacturing process steps are performed in addition to the multiple manufacturing process steps employed for the formation of field effect transistors in logic circuits and/or volatile memory circuits. In particular, dual gate oxide processes may be employed in the formation of flash memory cells. Due to the additional processing steps that are performed for forming the flash memory cells, providing nonvolatile memory in embedded systems may have a relatively high cost overhead.

Tiwari et al., “A silicon nanocrystals based memory,” Appl. Phys. Lett., 68:1377-79, 1996, discloses a memory structure using threshold shifting from charge stored in nanocrystals of silicon.

Tsuji et al., “Germanium nanoparticles formed in silicon dioxide layer by multi-energy implantation and oxidation state of Ge atoms,” Journal of Physics: Conference Series, 61:1196-1201, 2007, discloses a multi-energy implantation of Ge negative ions into an SiO₂ layer on a Si substrate. The Ge nanoparticles are said to be expected to be a promising light emission source.

Xu et al., “Self-assembled SiGe nanoparticles integrated into SOT,” Materials Letters, 72:39-41, 2012, discloses synthesizing SiGe nanoparticles in the top silicon of a silicon-on-insulator structure by Ge ion implantation combined with a subsequent annealing process.

The present disclosure provides semiconductor structures and methods for the formation thereof which may help to reduce the number of processing steps employed in the formation of nonvolatile memory cells on a same substrate as transistors in logic circuits and/or volatile memory circuits.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative semiconductor structure disclosed herein includes a support substrate including a semiconductor material, a buried insulation layer positioned above the support substrate, a semiconductor layer positioned above the buried insulation layer, the semiconductor layer having an upper surface and a lower surface, the lower surface being positioned on the buried insulation layer, and at least one nonvolatile memory cell. The nonvolatile memory cell includes a channel region, a front gate structure, a doped back gate region and a charge storage material. The channel region is located in the semiconductor layer. The front gate structure is located above the channel region and the upper surface of the semiconductor layer. The doped back gate region is located in the support substrate below the channel region. The charge storage material is embedded at least into a portion of the buried insulation layer between the channel region and the back gate region.

An illustrative method disclosed herein includes providing a semiconductor-on-insulator structure. The semiconductor-on-insulator structure includes a support substrate including a semiconductor material, a buried insulation layer positioned above the support substrate and a semiconductor layer positioned above the buried insulation layer, the semiconductor layer having an upper surface and a lower surface, the lower surface being positioned on the buried insulation layer. A nonvolatile memory cell is formed. The formation of the nonvolatile memory cell includes performing a first ion implantation process wherein first ions are implanted into a first portion of the buried insulation layer. After performing the first ion implantation process, an annealing process is performed wherein a charge storage material embedded into the first portion of the buried insulation layer is formed that comprises at least some of the implanted first ions. A doped back gate region is formed in the support substrate below the first portion of the buried insulation layer and a front gate structure is formed above a first portion of the semiconductor layer located above the first portion of the buried insulation layer.

### BRIEF DESCRIPTION OF THE DRAWINGS

The disclosure may be understood by reference to the following description taken in conjunction with the accompanying drawings, in which like reference numerals identify like elements, and in which:

FIG. 1 shows a schematic cross-sectional view of a semiconductor structure according to an embodiment;

FIGS. 2-5 show schematic cross-sectional views of the semiconductor structure of FIG. 1 in stages of a method of manufacturing a semiconductor structure according to an embodiment; and

FIG. 6 shows a schematic cross-sectional view of a semiconductor structure according to an embodiment in a stage of a method of manufacturing a semiconductor structure according to an embodiment.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

In embodiments disclosed herein, nonvolatile memory cells may be formed using a process flow wherein only a relatively small number of additional process steps are performed in addition to process steps employed for the formation of fully depleted semiconductor-on-insulator (FDSOI) transistors using standard process flows. Prior to a formation of shallow trench isolations and/or channel silicon germanium (cSiGe), a species that may be used for the formation of a nanoparticle floating gate may be implanted into a buried insulation layer of a fully depleted semiconductor-on-insulator structure by a masked ion implantation. A mask used in the ion implantation may be formed using a photolithographic process wherein krypton fluoride laser radiation is employed for exposing a photoresist. Argon fluoride laser radiation having a shorter wavelength than krypton fluoride laser radiation need not be employed in the implant mask. However, in alternative embodiments, argon fluoride laser radiation may also be employed. The implantation mask may define floating gate areas wherein floating gates of nonvolatile memory cells may be provided. Areas wherein no floating gates of nonvolatile memory cells are to be provided may be covered by the implantation mask. The implantation mask absorbs ions so that substantially no ions are implanted into the buried insulation layer in the areas wherein no floating gates are to be formed. The species implanted into the buried insulation layer may include ions of germanium, silicon, a metal, nitrogen and/or fluoride.

An annealing process may be performed to form nanoparticles on the basis of the species implanted into the buried insulation layer. The nanoparticles may be embedded into an electrically insulating material of the buried insulation layer such as, for example, silicon dioxide, and may be employed for the formation of nanoparticle floating gates of nonvolatile memory cells. The annealing process may be a furnace annealing process that is performed in a temperature range from about 900-1100° C. for approximately one hour, wherein, however, the temperature and the duration of the annealing process may vary depending on the species implanted into the buried insulation layer. In some embodiments, the annealing process may be a common annealing process that is also employed for a densification of an electrically insulating material in shallow trench isolations, for example, a high aspect ratio process (HARP) anneal.

Back gate regions, which may provide program/erase gates of nonvolatile memory cells, may be formed by performing well implants into portions of the support substrate below the floating gate areas. A shallow trench isolation structure may be formed to define nanoparticle floating gates of individual nonvolatile memory cells laterally. The formation of the shallow trench isolation structure may employ an immersion layer lithography.

Thereafter, in some embodiments, a conventional process for forming fully depleted semiconductor-on-insulator transistors may be performed to complete the formation of the nonvolatile memory cells, and to also form fully depleted semiconductor-on-insulator field effect transistors that may be employed in logic circuits and/or volatile memory circuits. In particular, front gate structures of the nonvolatile memory cells may be formed simultaneously with gate structures of field effect transistors. The front gate structures of the nonvolatile memory cells may include control gates of the nonvolatile memory cells.

Embodiments disclosed herein may provide a relatively easy integration of nonvolatile memory cells into process flows for the formation of integrated circuits, since processing at the front side of the fully depleted semiconductor-on-insulator structure need not be modified. Thus, front side topology may be identical to a base platform. Nonvolatile memory cells as disclosed herein may be well suited for NAND flash where programming and erase operations are performed by row.

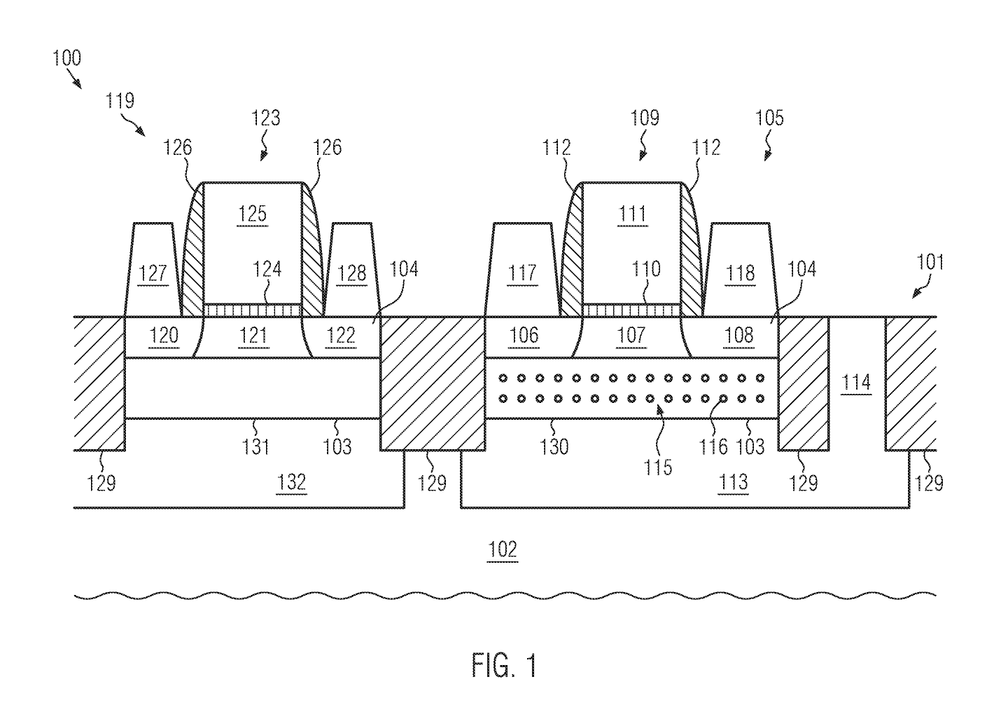

FIG. 1 shows a schematic cross-sectional view of a semiconductor structure 100 according to an embodiment. The semiconductor structure 100 may include a support substrate 102, a buried insulation layer 103 over the support substrate 102 and a semiconductor layer 104 over the buried insulation layer 103. In some embodiments, the support substrate 102 and the semiconductor layer 104 may include silicon and the buried insulation layer 103 may include silicon dioxide.

The semiconductor structure 100 may include a nonvolatile memory cell 105. The nonvolatile memory cell 105 may be part of a nonvolatile memory including a plurality of nonvolatile memory cells having a configuration corresponding to the configuration of the nonvolatile memory cell 105. In some embodiments, the nonvolatile memory may be a NAND flash memory.

The semiconductor structure 100 may further include a field effect transistor 119. The field effect transistor 119 may be provided in a logic circuit or a volatile memory circuit such as, for example, a static random access memory circuit or a dynamic random access memory circuit. Thus, the semiconductor structure 100 may include both nonvolatile memory circuits and logic and/or volatile memory circuits. In some embodiments, the semiconductor structure 100 may include a system on a chip, and it may be used, for example, for automotive and/or internet-of-things applications.

The semiconductor structure 100 may further include a trench isolation structure 129. The trench isolation structure 129 may include trenches extending through the semiconductor layer 104 and the buried insulation layer 103 into the support substrate 102 that are filled with an electrically insulating material such as, for example, silicon dioxide. The trench isolation structure 129 may provide an electrical insulation between the nonvolatile memory cell 105 and the field effect transistor 119, and it may electrically insulate the nonvolatile memory cell 105 and the field effect transistor 119 from other circuit elements in the semiconductor structure 100. In particular, in embodiments wherein the nonvolatile memory cell 105 is provided in a nonvolatile memory circuit including a plurality of nonvolatile memory cells, the trench isolation structure 129 may electrically insulate the nonvolatile memory cell 105 from other nonvolatile memory cells in the nonvolatile memory circuit.

The field effect transistor 119 need not be provided adjacent the nonvolatile memory cell 105, as schematically shown in FIG. 1. In other embodiments, the nonvolatile memory cell 105 and the field effect transistor 119 may be provided at a distance to each other. For example, the nonvolatile memory cell 105 may be provided in a nonvolatile memory area of the semiconductor structure 100, and the field effect transistor 119 may be provided in an area of the semiconductor structure 100 wherein logic circuits and/or volatile memory circuits are provided.

The support substrate 102, the buried insulation layer 103 and the semiconductor layer 104 may provide a semiconductor-on-insulator structure 101. In some embodiments, the semiconductor-on-insulator structure 101 may be a fully depleted semiconductor-on-insulator structure, wherein a thickness of the semiconductor layer 104 is adapted such that a full depletion of the channel regions of devices provided in the semiconductor structure 100, such as the nonvolatile memory cell 105 and the field effect transistor 119, may be obtained in the operation thereof. In some embodiments, the semiconductor layer 104 may have a thickness in a range from about 5-25 nm, for example, a thickness of about 7 nm. The buried insulation layer 103 may have a thickness in a range from about 5-30 nm, for example, a thickness of about 20 nm.

The nonvolatile memory cell 105 may include a source region 106, a channel region 107 and a drain region 108 that are provided in a portion of the semiconductor layer 104 in the nonvolatile memory cell 105. The source region 106 and the drain region 108 are provided on opposite sides of the channel region 107. In some embodiments, the nonvolatile memory cell 105 may be an N-channel nonvolatile memory cell, wherein the source region 106 and the drain region 108 are N-doped. The channel region 107 may have a doping that is different from the doping of the source region 106 and the drain region 108. For example, the channel region 107 may be P-doped or substantially undoped. Over the source region 106, a raised source region 117 may be provided, and a raised drain region 118 may be provided over the drain region 108. The raised source and drain regions 117, 118 may have a doping of the same type as the doping of the source region 106 and the drain region 108.

Over the channel region 107, a front gate structure 109 of the nonvolatile memory cell 105 may be provided. The front gate structure 109 is provided at a front side of the semiconductor structure 100, which is a side of the semiconductor layer 104 opposite the buried insulation layer 103 and the support substrate 102.

The front gate structure 109 may include a gate insulation layer 110, a control gate 111 of the nonvolatile memory cell 105 and one or more sidewall spacers 112 adjacent the control gate 111.

Additionally, the nonvolatile memory cell 105 may include a doped back gate region 113 that is provided in the substrate 102 below the channel region 107. Additionally, as shown in FIG. 1, the back gate region 113 may be provided below the source region 106 and the drain region 108. The back gate region 113 may have a doping that is different from a base doping of the support substrate 102. In embodiments wherein the nonvolatile memory cell 105 is an N-channel nonvolatile memory cell, the back gate region 113 may be N-doped. The base doping of the support substrate 102 may be a P-type doping. Thus, there may be a PN transition between the back gate region 113 and portions of the support substrate 102 other than the back gate region 113, which may provide an electrical insulation between the back gate region 113 and other portions of the support substrate 102 in the operation of the semiconductor structure 100.

The semiconductor structure 100 may include a back gate contact region 114. The back gate contact region 114 may include a semiconductor material having a doping that corresponds to the doping of the back gate region 113. In embodiments wherein the back gate region 113 is N-doped, the back gate contact region 114 may also be N-doped. The back gate contact region 114 may be continuous with the back gate region 113. Herein, two doped semiconductor regions, such as the back gate contact region 114 and the back gate region 113, are denoted as being continuous with each other, if there is an electrically conductive path without a PN transition between the doped semiconductor regions. As shown in FIG. 1, the back gate contact region 114 may extend through the buried insulation layer 103 to a plane of the semiconductor layer 104. A portion of the trench isolation structure 129 may separate the back gate contact region 114 from the portion of the semiconductor layer 104 in the nonvolatile memory cell 105, and from the portion of the buried insulation layer 103 there below. Thus, the back gate contact region 114 may be electrically insulated from the source 106, channel 107 and drain 108 regions of the nonvolatile memory cell 105.

The nonvolatile memory cell 105 may further include a charge storage material 115 that is embedded into the portion of the buried insulation layer 103 in the nonvolatile memory cell 105. In particular, the charge storage material 115 may be embedded into the portion of the buried insulation layer 103 between the channel region 107 and the back gate region 113. Additionally, the charge storage material 115 may be embedded into portions of the buried insulation layer 103 between the source 106 and drain 108 regions and the back gate region 113. In such embodiments, the entire nonvolatile memory cell 105 may be provided at a part 130 of the buried insulation layer 103 including the charge storage material 115.

The charge storage material 115 may be provided in a region of the buried insulation layer 103 at approximately a center of the buried insulation layer 103, so that a relatively large amount of the charge storage material 115 is provided in a region at approximately the center of the buried insulation layer 103, whereas a smaller amount of the charge storage material 115 or substantially no charge storage material 115 is provided in regions of the buried insulation layer 103 at an interface between the buried insulation layer 103 and the semiconductor layer 104 and in regions at an interface between the charge storage layer 103 and the support substrate 102.

In some embodiments, the charge storage material 115 may include a semiconductor material, for example, germanium, silicon and/or silicon germanium. In other embodiments, the charge storage material 115 may include a metal. In further embodiments, the charge storage material 115 may include an electrically insulating material that is different from the electrically insulating material from which the buried insulation layer 103 is formed. In embodiments wherein the buried insulation layer 103 is a silicon dioxide layer, the charge storage material 115 may include a chemical compound including at least one of nitrogen and fluoride, for example, silicon nitride or silicon oxynitride.

The charge storage material 115 may be provided in the form of nanoparticles of the charge storage material 115 that are embedded into the material of the buried insulation layer 103. In FIG. 1, one nanoparticle is exemplarily denoted by reference numeral 116. The nanoparticles may have a diameter in a range from about 2-5 nm, depending on the formation process, and they may be surrounded by the material of the buried insulation layer 103, so that they are electrically insulated and electrically floating. If an electric charge is provided at the nanoparticles 116 of the charge storage material 115, an electric field of the electric charge may act on the material of the semiconductor layer 104 in the channel region 107, so that the electric charge of the nanoparticles 116 of the charge storage material 115 may have an influence on a threshold voltage that needs to be applied to the control gate 111 for obtaining an electrically conductive channel in the channel region 107 between the source region 106 and the drain region 108.

Since the nanoparticles 116 of the charge storage material 115 are surrounded by the electrically insulating material of the buried insulation layer 103, an electric charge of the charge storage material 115 may remain stored for a relatively long time, and may be used for storing a bit of information in the nonvolatile memory cell 105, wherein a logical “1” and a logical “0” are represented by different amounts of charge of the charge storage material 115. Thus, the charge storage material 115 may provide a floating gate of the nonvolatile memory cell 105.

For reading the bit of data stored in the nonvolatile memory cell 105, a voltage may be applied between the source region 106 and the drain region 108, and a gate voltage may be applied to the control gate 111. A current flowing between the source region 106 and the drain region 108 that depends on the amount of charge stored in the charge storage material 115 may be measured by means of a sense amplifier (not shown).

The back gate region 113 may provide a program/erase gate of the nonvolatile memory cell 105. For programming the nonvolatile memory cell 105, an electrical voltage that is more negative than a voltage applied to the source and drain regions 106, 108 and/or the control gate 111 may be applied to the back gate region 113 via the back gate contact region 114 so that electrons can tunnel from the back gate region 113 to the charge storage material 115 in the buried insulation layer 103 and the charge storage material 115 is electrically charged.

For erasing the nonvolatile memory cell 105, an electrical voltage that is more positive than a voltage applied to the source and drain regions 106, 108 and/or the control gate 111 may be applied to the back gate region 113 via the back gate contact region 114, so that electrons can tunnel from the charge storage material 115 through the electrically insulating material of the buried insulation layer 103 into the back gate region 113.

Typical voltages applied for programming and erasing may be in a range from about 3-5 V, whereas the read operation may be performed in the usual voltage regime of a power supply voltage (Vdd) of the integrated circuit wherein the nonvolatile memory cell 105 is provided.

In some embodiments, the nonvolatile memory cell 105 may be provided in a NAND flash memory, wherein the back gate regions 113 of a plurality of nonvolatile memory cells are continuous with each other. In such embodiments, a single back gate contact region 114 may be provided for two or more of the nonvolatile memory cells.

The present disclosure is not limited to embodiments wherein the nonvolatile memory cell 105 is an N-channel nonvolatile memory cell. In other embodiments, the nonvolatile memory cell 105 may be a P-channel nonvolatile memory cell, wherein the source and drain regions 106, 108 and the raised source and drain regions 117, 118, as well as the back gate region 113 and the back gate contact region 114, are P-doped.

The field effect transistor 119 may include a source region 120, a channel region 121 and a drain region 122 that are provided in the semiconductor layer 104 of the semiconductor-on-insulator structure 101. Over the source region 120, a raised source region 127 may be provided, and a raised drain region 128 may be provided over the drain region 122. Additionally, the field effect transistor 119 may include a gate structure 123 that includes a gate insulation layer 124 and a gate 125 of the field effect transistor 119. Adjacent the gate 125, a sidewall spacer 126 may be provided. In some embodiments, a back gate region 132 that is not continuous with the back gate region 113 of the nonvolatile memory cell 105 may be provided below the source, channel and drain regions 120, 121, 122 of the field effect transistor 119. In the operation of the semiconductor structure 100, in some embodiments, a voltage may be applied to the back gate region 132 by means of a back gate contact (not shown) having features similar to those of the back gate contact 114 for controlling a threshold voltage of the field effect transistor 119.

In some embodiments, the field effect transistor 119 may be an N-channel transistor wherein the source region 120, the drain region 122, the raised source region 127 and the raised drain region 128 are N-doped and the channel region 121 is P-doped or substantially undoped. The back gate region 132 may have a doping different from the base doping of the support substrate 102, and it may be P-doped or N-doped.

The field effect transistor 119 may be provided at a part 131 of the buried insulation layer 103 that does not include charge storage material. In some embodiments, a configuration of the field effect transistor 119 may correspond to a configuration of conventional fully depleted semiconductor-on-insulator field effect transistors.

In some embodiments, a configuration of the gate structure 109 of the nonvolatile memory cell 105 may be similar to a configuration of the gate structure 123 of the field effect transistor 119. In particular, the gate insulation layer 110 may be formed of substantially the same one or more materials as the gate insulation layer 124, the control gate 111 may be formed of substantially the same one or more materials as the gate 125 of the field effect transistor 119, and the sidewall spacer 112 may be formed of substantially the same one or more materials as the sidewall spacer 126. In some embodiments, the gate insulation layers 110, 124 may include a high-k dielectric material having a greater dielectric constant than silicon dioxide such as, for example, hafnium dioxide, zirconium dioxide, hafnium zirconium oxide and/or hafnium silicate. The control gate 111 and the gate 125 of the field effect transistor 119 may include a metal, for example, a layer of a work function adjustment metal (not shown) over the gate insulation layers 110, 124 and/or polysilicon. The sidewall spacers 112, 126 may include silicon dioxide, silicon nitride and/or silicon oxynitride.

For providing electrical connections to the nonvolatile memory cell 105 and the field effect transistor 119, an interlayer dielectric including contact holes filled with an electrically conductive material and one or more interconnect layers including contact vias and electrically conductive lines (not shown) may be provided over the semiconductor structure 100 for contacting the nonvolatile memory cell 105 and the field effect transistor 119. Furthermore, a silicide (not shown) may be provided in some or all of the raised source regions 117, 127, the raised drain regions 118, 128, the control gate 111, the gate 125 and the back gate contact region 114. Features of these elements may correspond to those conventionally employed in integrated circuits, and conventional methods may be used for the formation thereof. Therefore, a detailed description of these elements and methods that may be employed for the formation thereof will be omitted herein.

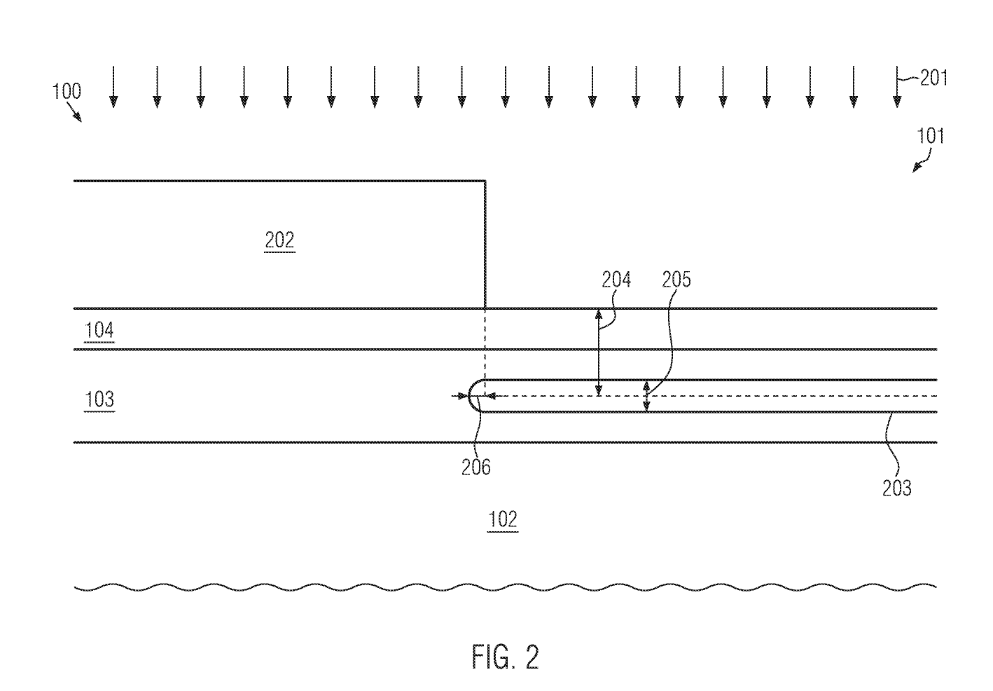

In the following, methods that may be employed for forming the semiconductor structure described above with reference to FIG. 1 will be described with reference to FIGS. 2-5.

FIG. 2 shows a schematic cross-sectional view of the semiconductor structure 100 at a stage of a method of manufacturing the semiconductor structure 100 according to an embodiment. The semiconductor-on-insulator structure 101 including the support substrate 102, the buried insulation layer 103 and the semiconductor layer 104 may be provided. This may be done by means of known techniques for the formation of semiconductor-on-insulator structures. In some embodiments, the buried insulation layer 103 may be formed on a surface of a sacrificial wafer, and the sacrificial wafer having the buried insulation layer 103 formed thereon may be bonded to the support substrate 102. Thereafter, the sacrificial wafer may be cleaved. A portion of the sacrificial wafer may remain on the buried insulation layer 103, and may provide the semiconductor layer 104.

A mask 202 may be formed over the semiconductor-on-insulator structure 101. The mask 202 may be a photoresist mask and it may be formed by a means of a photolithography process. In some embodiments, for forming the mask 202, a layer of a photoresist may be exposed using krypton fluoride laser radiation which may be created by means of a krypton fluoride excimer laser. For forming the mask 202, krypton fluoride laser radiation having a longer wavelength than argon fluoride laser radiation created by means of an argon fluoride excimer laser may be sufficient in view of the optical resolution requirements for forming the mask 202. However, in other embodiments, argon fluoride laser radiation may also be used. The mask 202 may cover portions of the semiconductor structure 100 other than those wherein the charge storage material 115 is to be provided. Thus, the mask 202 may define areas of the semiconductor structure wherein floating gates of nonvolatile memory cells, such as the nonvolatile memory cell 105 including a floating gate provided by the charge storage material 115, are formed.

After the formation of the mask 202, an ion implantation process that is denoted by reference numeral 201 in FIG. 2 may be performed. In the ion implantation process, the semiconductor structure 100 may be irradiated with ions of a material that is used for forming the charge storage material 115. In embodiments wherein the charge storage material 115 includes germanium, in the ion implantation process 201, the semiconductor structure 100 may be irradiated with germanium ions. In embodiments wherein the charge storage material 115 includes silicon germanium, the semiconductor structure 100 may be irradiated with silicon ions and germanium ions. In embodiments wherein the charge storage material 115 includes silicon, the semiconductor structure 100 may be irradiated with silicon ions. In embodiments wherein the charge storage material 115 includes a metal, the semiconductor structure 100 may be irradiated with ions of the respective metal in the ion implantation process 201. In embodiments wherein the charge storage material 115 includes a chemical compound including nitrogen or fluorine, the semiconductor structure 100 may be irradiated with nitrogen or fluorine ions.

An ion dose employed in the ion implantation process 201 may be selected in accordance with an amount of the charge storage material 115 per area that is to be provided in the portion of the buried insulation layer 103 having the charge storage material 115 embedded therein.

An ion energy used in the ion implantation process 201 may be selected such that a majority of the ions comes to rest at approximately the center of the buried insulation layer 103 and forms an implanted region 203 in the buried insulation layer 103. In FIG. 2, reference numeral 204 denotes a projected range of the ion implantation process 201, being a distance from the surface of the semiconductor structure 100 at which the greatest concentration of the species implanted into the semiconductor structure 100 in the ion implantation process 201 is obtained.

Reference numeral 205 denotes a longitudinal straggle, being a standard deviation of the distribution of implanted material along the vertical direction of the semiconductor structure 100, which corresponds to the direction of implantation of the ions (vertical in the plane of drawing of FIG. 2). Reference numeral 206 denotes a lateral straggle, being a standard deviation of the difference between the position at which an ion comes to rest in the buried insulation layer 103 from the position at which the ion impinges on the surface of the semiconductor structure 100 in the lateral direction (horizontal in the plane of drawing of FIG. 2). Due to the lateral straggle of ions, the implanted region 203 may extend below the edges of the mask 202 to a certain extent. However, portions of the buried insulation layer 103 below the mask 202, which are at a distance to the edges of the mask 202 substantially greater than the lateral straggle 206, may be substantially protected from an irradiation with ions in the ion implantation process 201. Thus, a portion of the buried insulation layer 103 having substantially no ions implanted therein, which corresponds to the portion 131 (FIG. 1) of the buried insulation layer 103 having substantially no charge storage material embedded therein, may be formed.

Portions of the semiconductor structure 100 that are not covered by the mask 202, but which are spaced apart from the plane of greatest concentration of the implanted species represented by the projected range 204 of the ion implantation process 201 in the vertical direction by a distance that is substantially greater than the longitudinal straggle 205 may receive only a small amount of ions in the ion implantation process 201. Thus, an implantation of ions into the semiconductor layer 104 and an implantation of ions into the support substrate 102 in the ion implantation process 201 may be substantially avoided or at least reduced. Furthermore, only a small concentration of implanted species may be obtained in the buried insulation layer 103 in the vicinity of the interface between the buried insulation layer 103 and the semiconductor layer 104 and in the vicinity of the interface between the buried insulation layer 103 and the support substrate 102. Moreover, an upper damage edge of the ion implantation process 201, being a distance from the surface of the semiconductor structure 100 that is smaller than the projected range 204 by 1.5 times the longitudinal straggle, may be within the buried insulation layer 103, so that a damage of the semiconductor layer 104 by the implantation of ions may be substantially avoided or reduced.

In embodiments wherein the semiconductor structure 100 is irradiated with germanium ions in the ion implantation process 201, the buried insulation layer 103 has a thickness of approximately 20 nm and the semiconductor layer 104 has a thickness of approximately 7 nm, an ion energy used in the ion implantation process 201 may be approximately 15 keV, so that a projected range 204 of the ion implantation of about 16 nm is obtained, which is about 9 nm below the interface between the buried insulation layer 103 and the semiconductor layer 204. Thus, a maximum concentration of implanted species may be obtained close to the center of the buried insulation layer 103. In such embodiments, a longitudinal straggle of about 6 nm may be obtained, which may be sufficient for obtaining a relatively small concentration of implanted species at the interfaces between the buried insulation layer 103 and the support substrate 102 and the semiconductor layer 104, and for substantially avoiding or at least reducing damages of the semiconductor layer 104. In some embodiments, an ion dose used in the ion implantation process may be in a range from about 2·10¹⁵ ions/cm² to about 5·10¹⁵ ions/cm².

In other embodiments, different parameters of the ion implantation process 201 may be used. In the following table, the projected range 204, the longitudinal straggle 205, the lateral straggle 206 and the depth of the upper damage edge from the surface of the semiconductor layer 104 are provided for different ion energies of an implantation of germanium ions into silicon. Since the stopping powers of silicon and silicon dioxide for germanium ions are approximately equal, these values are also valid for the implantation of germanium ions into the semiconductor-on-insulation structure 101 in embodiments wherein the support substrate 102 and the semiconductor layer 104 include silicon and the buried insulation layer 103 includes silicon dioxide.

| Ion | Projected | | | Upper Damage |
|---|---|---|---|---|
| Energy | Range | Longitudinal | Lateral | Edge |
| (keV) | Rₚ (Å) | Straggle s (Å) | Straggle (Å) | Rₚ - 1.5 s (Å) |
| 2 | 50 | 22 | 16 | 17 |
| 2.25 | 53 | 23 | 17 | 18.5 |
| 2.5 | 56 | 24 | 18 | 20 |
| 2.75 | 59 | 25 | 18 | 21.5 |
| 3 | 62 | 26 | 19 | 23 |
| 3.25 | 64 | 27 | 20 | 23.5 |
| 3.5 | 67 | 28 | 21 | 25 |
| 3.75 | 70 | 29 | 21 | 26.5 |
| 4 | 72 | 30 | 22 | 27 |
| 4.5 | 77 | 32 | 23 | 29 |
| 5 | 82 | 33 | 25 | 32.5 |
| 5.5 | 87 | 35 | 26 | 34.5 |
| 6 | 92 | 36 | 27 | 38 |
| 6.5 | 96 | 38 | 28 | 39 |
| 7 | 100 | 39 | 30 | 41.5 |
| 8 | 109 | 42 | 32 | 46 |
| 9 | 117 | 45 | 34 | 49.5 |
| 10 | 126 | 48 | 36 | 54 |
| 11 | 134 | 50 | 38 | 59 |
| 12 | 141 | 53 | 40 | 61.5 |
| 13 | 149 | 55 | 42 | 66.5 |
| 14 | 157 | 57 | 44 | 71.5 |
| 15 | 164 | 60 | 46 | 74 |
| 16 | 171 | 62 | 48 | 78 |
| 17 | 179 | 64 | 49 | 83 |
| 18 | 186 | 66 | 51 | 87 |
| 20 | 200 | 71 | 54 | 93.5 |
| 22.5 | 218 | 76 | 59 | 104 |
| 25 | 235 | 81 | 63 | 113.5 |
| 27.5 | 252 | 86 | 67 | 123 |
| 30 | 269 | 91 | 70 | 132.5 |

In embodiments wherein ions other than germanium ions are implanted into the semiconductor structure 100, other parameters of the ion implantation process may be used.

In some embodiments, the ion implantation process 201 may be a hot chuck ion implantation process that is performed at a temperature greater than room temperature, in particular, greater than about 20° C., for example, in a temperature range up to about 450° C. This may be done by means of a known hot chuck ion implanter. Performing the ion implantation process 201 at an elevated temperature may help to substantially avoid or at least reduce an amorphization of the buried insulation layer 103 in the ion implantation process 201.

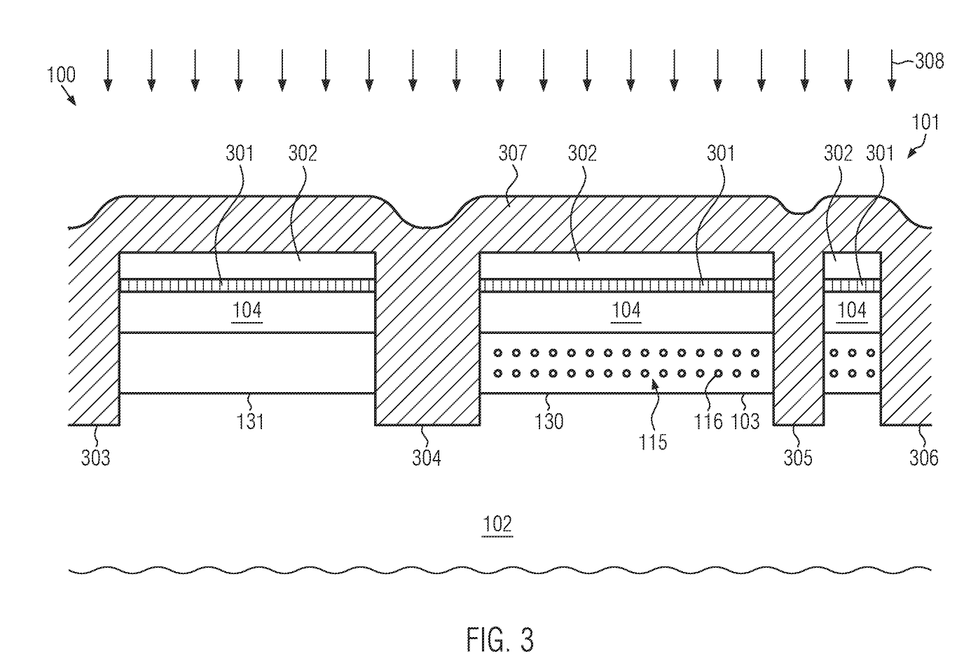

FIG. 3 shows a schematic cross-sectional view of the semiconductor structure 100 at a later stage of the method of manufacturing the semiconductor structure 100. After the ion implantation process 201, the mask 202 may be removed by means of a resist strip process. Then, in some embodiments, channel silicon germanium may be formed in portions of the semiconductor layer 104. This may be done by forming a layer of silicon germanium over the silicon germanium region 105, performing an oxidation process wherein silicon from the silicon germanium layer is oxidized and the germanium diffuses into portions of the silicon layer therebelow, and removing silicon dioxide formed in the oxidation process. In other embodiments, the formation of channel silicon germanium may be omitted.

Thereafter, the trench isolation structure 129 may be formed. A pad layer 301, which may include silicon dioxide and a hardmask layer 302 which may include silicon nitride may be formed over the semiconductor structure 100 using techniques of oxidation and/or deposition. Thereafter, the pad layer 301 and the hardmask layer 302 may be patterned by means of techniques of photolithography and etching for forming a hardmask covering the semiconductor structure 100 with the exception of portions of the semiconductor structure 100 wherein the trench isolation structure 129 is to be formed. In some embodiments, in the photolithography process used for forming the hardmask from the pad layer 301 and the hardmask layer 302, immersion layer lithography may be used.

Thereafter, one or more etch processes may be performed for forming trenches 303, 304, 305, 306 extending through the semiconductor layer 104 and the buried insulation layer 103 into the support substrate 102 at portions of the semiconductor structure 100 that are not covered by the hardmask. Then, a layer 307 of electrically insulating material, which may include silicon dioxide, may be formed over the semiconductor structure 100. In some embodiments, the layer 307 of electrically insulating material may include a plurality of sub-layers, for example, a liner layer that may include silicon dioxide and a fill layer, which may also include silicon dioxide, and is provided over the liner layer. For forming the liner layer and the fill layer, different processes may be employed. For example, different deposition processes may be employed for forming the liner layer and the fill layer that are optimized to remove implant damage and thus the quality of the tunneling oxide. Furthermore, in some embodiments, the formation of the liner layer may include an oxidation process wherein silicon dioxide is formed by oxidizing material of the semiconductor layer 104 and/or the support substrate 102.

After the formation of the layer 307 of electrically insulating material, an annealing process 308 may be performed. In the annealing process 308, the charge storage material 115 may be formed on the basis of the ions implanted into the semiconductor structure 100 in the ion implantation process 201. In embodiments wherein germanium, silicon or a metal has been implanted into the semiconductor structure 100 in the ion implantation process 201, nanoparticles including the respective materials may be formed. In other embodiments, for example, in embodiments wherein nitrogen and/or fluorine has been implanted into the semiconductor structure 100, the implanted species may chemically react with the material of the buried insulation layer 103, so that chemical compounds including nitrogen and/or fluorine may be formed.

Additionally, the annealing process 308 may densify the electrically insulating material 307, similar to annealing processes employed in conventional high aspect ratio processes (HARP) used in the formation of shallow trench isolation structures.

In embodiments wherein germanium has been implanted into the semiconductor structure 100 in the ion implantation process 201, the annealing process 308 may be performed at a temperature in a range from about 900-1100° C., for example, at a temperature of about 1000° C., and an annealing time after temperature ramp may be in a range from about 30-90 minutes, for example, about one hour. The annealing process 308 may be performed by inserting the semiconductor structure in a furnace that is heated to the anneal temperature.

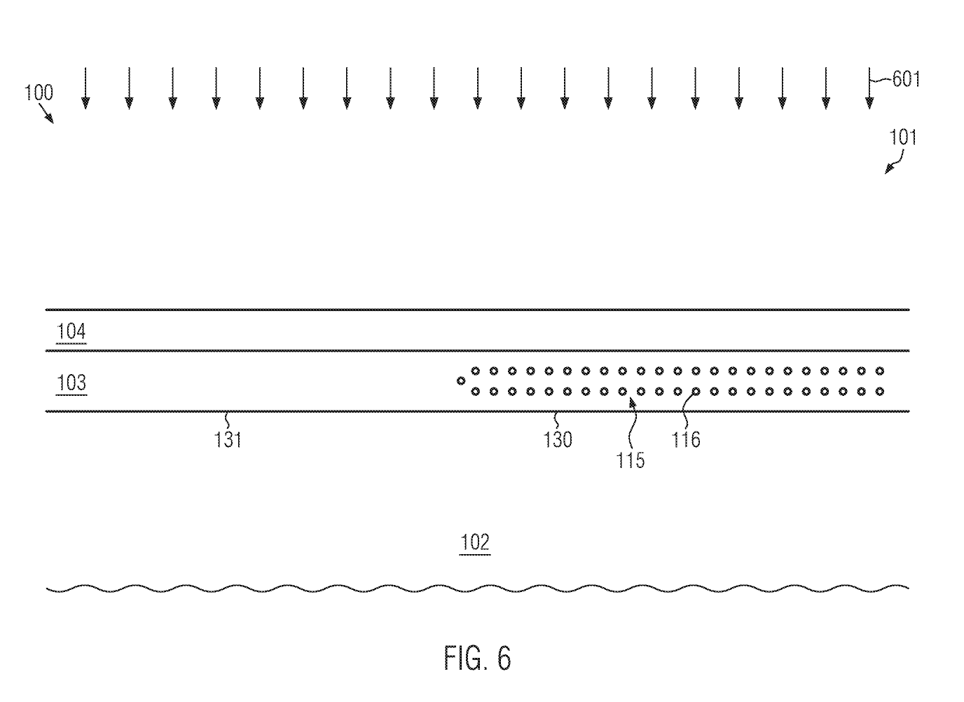

The present disclosure is not limited to embodiments wherein the formation of the charge storage material 115 on the basis of the ions implanted into the buried insulation layer 103 is combined with a densification of the layer 307 of electrically insulating material. In other embodiments, an annealing process wherein the charge storage material is formed may be performed at a different stage of the method of manufacturing the semiconductor structure 100. Examples of such embodiments will be described with reference to FIG. 6 below.

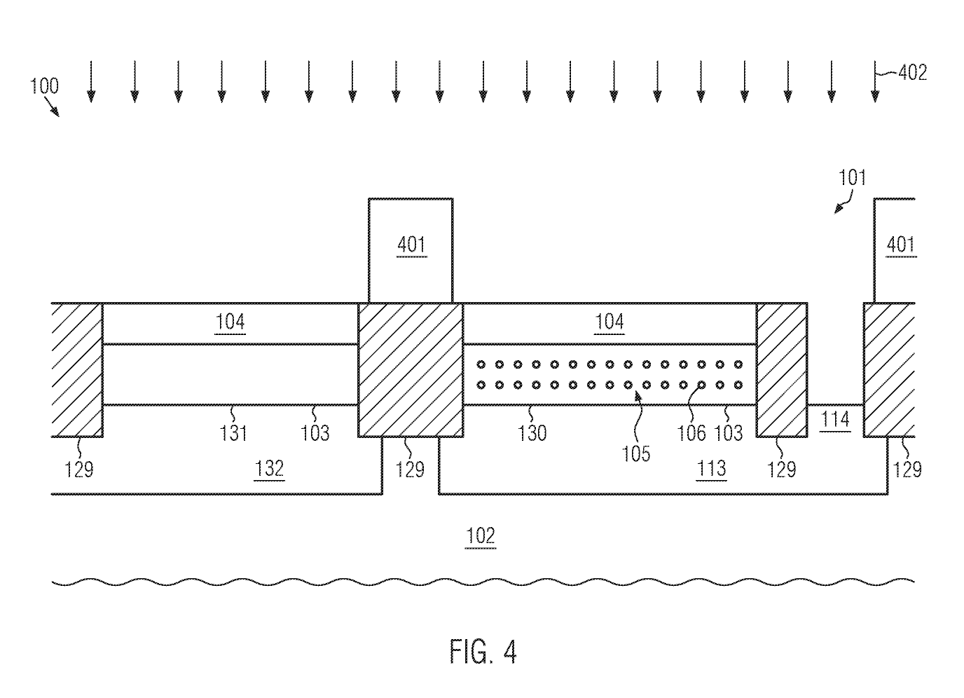

FIG. 4 shows a schematic cross-sectional view of the semiconductor structure 100 at a later stage of the method of manufacturing the semiconductor structure 100. After the formation of the layer 307 of electrically insulating material and the annealing process 308, a chemical mechanical polishing process may be performed for removing portions of the layer 307 of electrically insulating material outside the trenches 303, 304, 305, 306. Portions of the layer 307 of electrically insulating material in the trenches 303, 304, 305, 306 may remain in the semiconductor structure 100, and may provide the trench isolation structure 129.

Thereafter, portions of the semiconductor layer 104 and the buried insulation layer 103 at the location of the back gate contact region 114 may be removed by techniques of photolithography and etching for exposing the semiconductor material of the support substrate 102 in the back gate contact region 114.

Additionally, an ion implantation process 402 wherein the semiconductor structure 100 is irradiated with ions of a dopant employed for doping the back gate regions 113, 132 of the nonvolatile memory cell 105 and the field effect transistor 119 may be performed. Portions of the semiconductor structure 100 wherein the back gate regions 113, 132 are not to be provided may be covered by a mask 401. The mask 401 may be a photoresist mask, and it may be formed by means of photolithography techniques. The mask 401 may protect portions of the semiconductor structure 100 below the mask 401 from being irradiated with ions in the ion implantation process 402. Thus, the back gate regions 113, 132 may be formed separated from each other.

The present disclosure is not limited to embodiments wherein the back gate regions 113, 132 have the same type of doping. In other embodiments, the back gate regions 113, 132 may be differently doped. In such embodiments, one of the back gate regions 113, 132 may be covered by a mask while ions are implanted into the other one of the back gate regions 113, 132.

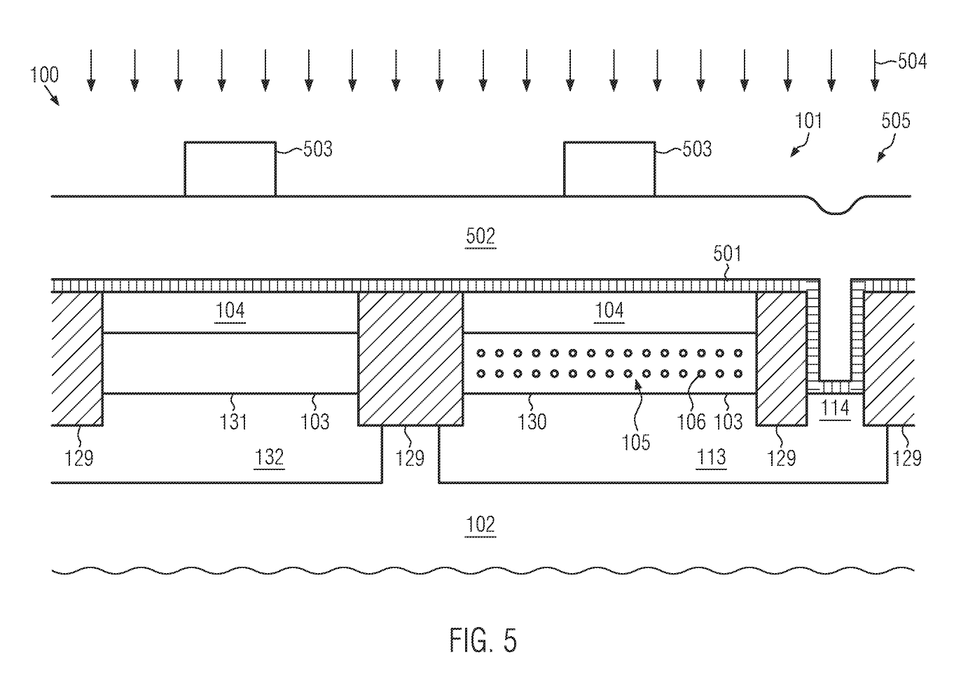

FIG. 5 shows a schematic cross-sectional view of the semiconductor structure 100 at a later stage of the method of manufacturing the semiconductor structure 100. After the ion implantation process 402, the mask 401 may be removed and a gate stack 505 may be formed over the semiconductor structure 100. The gate stack 505 may include a layer 501 of a gate insulation material and a layer 502 of gate electrode material. In some embodiments, the layers 501, 502 may include the materials of the gate insulation layers 110, 124 and the gates 111, 125 of the nonvolatile memory cell 105 and the field effect transistor 119. In other embodiments, the control gate structure 109 of the nonvolatile memory cell 105 and the gate structure 123 of the field effect transistor 119 may be formed by means of a replacement gate process. In such embodiments, the layer 501 of gate insulation material may include a dummy gate insulation material, for example, silicon dioxide, and the layer 502 of gate electrode material may include a dummy gate electrode material, for example, polysilicon. Additionally, the gate stack 505 may include a layer of a hardmask material, for example, silicon nitride. The layer of hardmask material may be patterned by means of techniques of photolithography and etching to form a hardmask 503 covering portions of the semiconductor structure 100 at which the control gate structure 109 and the gate structure 123 of the field effect transistor 119 are to be formed. Then, one or more etch processes 504 may be performed for removing portions of the gate stack 505 that are not covered by the hardmask 503, wherein the control gate structure 109 and the gate structure 123 of the field effect transistor 119 are formed.

Thereafter, further processing steps may be performed for obtaining the configuration of the semiconductor structure 100 shown in FIG. 1. In particular, the sidewall spacers 112, 126 may be formed by depositing one or more layers of one or more sidewall spacer materials over the semiconductor structure 100 and performing one or more anisotropic etch processes for removing portions of the one or more layers of sidewall spacer material over substantially horizontal portions of the semiconductor structure 100.

Thereafter, a selective epitaxial growth process may be performed for forming the raised source regions 117, 127 and the raised drain regions 118, 128. Additionally, the selective epitaxial growth process may deposit semiconductor material at the back gate contact region 114, so that a height difference between the surface of the back gate contact region 114 and the surface of the semiconductor layer 104 is reduced. The selective epitaxial growth process may be a deposition process that is adapted such that doped semiconductor material is deposited over portions of the semiconductor structure 100 at which semiconductor material is exposed, and substantially no doped semiconductor material or only a small amount of doped semiconductor material is deposited over portions of the semiconductor structure 100 covered by other materials such as silicon dioxide or silicon nitride. Then, an annealing process may be performed for activating the dopants implanted into the back gate regions 113, 132, and for diffusing dopants from the raised source regions 117, 127 and the raised drain regions 118, 128 into portions of the semiconductor layer 104 therebelow, wherein the source regions 106, 120 and the drain regions 108, 122 are formed.

As already mentioned above, the present disclosure is not limited to embodiments wherein an annealing process that is performed for forming the charge storage material 115 on the basis of the ions implanted into the buried insulation layer 103 is also used for densifying the layer 307 of electrically insulating material.

FIG. 6 shows a schematic cross-sectional view of the semiconductor structure 100 at a stage of an alternative embodiment of a method of forming the semiconductor structure 100. After the ion implantation process 201 described above with reference to FIG. 2, the mask 202 may be removed, and an annealing process 601 may be performed. Features of the annealing process 601, such as the temperature at which the annealing process 601 is performed and the duration of the annealing process 601, may correspond to those of the annealing process 308 described above with reference to FIG. 3. In the annealing process 601, nanoparticles of the charge storage material 115, one of which being denoted by reference numeral 116, may be formed on the basis of the ions implanted into the buried insulation layer 103 in the ion implantation process 201.

After the annealing process 601, the method of manufacturing the semiconductor structure 100 may continue with an optional formation of silicon germanium regions in the semiconductor layer 104, and the formation of the trench isolation structure 129, which may be performed as described above with reference to FIG. 3. Thereafter, further steps of the manufacturing process may be performed as described above with reference to FIGS. 4 and 5 for completing the formation of the semiconductor structure 100.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A semiconductor structure, comprising:
a support substrate comprising a semiconductor material, a buried insulation layer positioned above said support substrate and a semiconductor layer positioned above said buried insulation layer, said semiconductor layer having an upper surface and a lower surface, said lower surface being positioned on said buried insulation layer; and
at least one nonvolatile memory cell, said at least one nonvolatile memory cell comprising:
a channel region located in said semiconductor layer;
a front gate structure located above said channel region and said upper surface of said semiconductor layer;
a doped back gate region located in said support substrate below said channel region; and
a charge storage material embedded at least into a portion of said buried insulation layer between said channel region and said back gate region, wherein said charge storage material comprises at least one of silicon or germanium.

2. The semiconductor structure of claim 1, wherein said front gate structure comprises a gate insulation layer and a control gate, and wherein said doped back gate region provides a program/erase gate.

3. The semiconductor structure of claim 2, wherein said at least one nonvolatile memory cell further comprises a source region and a drain region located in said semiconductor layer on opposite sides of said channel region, a raised source region positioned above said source region and a raised drain region positioned above said drain region.

4. The semiconductor structure of claim 3, wherein said buried insulation layer comprises a portion having substantially no charge storage material embedded therein, and wherein said semiconductor structure further comprises at least one field effect transistor, said at least one field effect transistor comprising a source region, a channel region and a drain region located in said semiconductor layer above said portion of said buried insulation layer having substantially no charge storage material embedded therein and a gate structure positioned above said channel region.

5. The semiconductor structure of claim 4, further comprising a trench isolation structure, wherein a part of said buried insulation layer in said nonvolatile memory cell is laterally defined by said trench isolation structure.

6. The semiconductor structure of claim 5, wherein said charge storage material comprises nanoparticles of said charge storage material embedded into a material of said buried insulation layer.

7. The semiconductor structure of claim 6, further comprising a back gate contact region providing an electrical connection to at least one of said doped back gate region of said at least one nonvolatile memory cell.

8. (canceled)

9. A method, comprising:
providing a semiconductor-on-insulator structure comprising a support substrate comprising a semiconductor material, a buried insulation layer positioned above said support substrate and a semiconductor layer positioned above said buried insulation layer, said semiconductor layer having an upper surface and a lower surface, said lower surface being positioned on said buried insulation layer; and
forming a nonvolatile memory cell, the formation of said nonvolatile memory cell comprising:
performing a first ion implantation process wherein first ions are implanted into a first portion of said buried insulation layer, wherein said first ions comprise at least one of silicon or germanium;
after performing said first ion implantation process, performing an annealing process wherein a charge storage material embedded into said first portion of said buried insulation layer is formed that comprises at least some of said implanted first ions;
forming a doped back gate region in said support substrate below said first portion of said buried insulation layer; and
forming a front gate structure above a first portion of said semiconductor layer located above said first portion of said buried insulation layer.

10. The method of claim 9, further comprising forming a mask before performing said first ion implantation process, said mask defining said first portion of said buried insulation layer into which said first ions are implanted during said first ion implantation process and a second portion of said buried insulation layer into which substantially none of said first ions are implanted during said first ion implantation process.

11. The method of claim 10, wherein said formation of said doped back gate region comprises performing a second ion implantation process wherein second ions are implanted into a portion of said support substrate below said first portion of said buried insulation layer, said second ions comprising ions of a dopant.

12. The method of claim 11, further comprising, after performing said first ion implantation process, forming a trench isolation structure, said trench isolation structure laterally defining a part of said first portion of said buried insulation layer in said nonvolatile memory cell.

13. The method of claim 12, further comprising forming a gate structure of a field effect transistor above a second portion of said semiconductor layer positioned above said second portion of said buried insulation layer, wherein said gate structure of said field effect transistor and said front gate structure of said nonvolatile memory cell are formed in a common gate formation process.

14. The method of claim 13, further comprising:
forming a source region of said nonvolatile memory cell and a drain region of said nonvolatile memory cell in said semiconductor layer adjacent said front gate structure of said nonvolatile memory cell, a part of said semiconductor layer positioned below said front gate structure providing a channel region of said nonvolatile memory cell; and
forming a source region of said field effect transistor and a drain region of said field effect transistor in said semiconductor layer adjacent said gate structure of said field effect transistor, a part of said semiconductor layer positioned below said gate structure of said field effect transistor providing a channel region of said field effect transistor;
wherein said formation of said source and drain regions of said field effect transistor and said nonvolatile memory cell comprises:
forming a respective doped raised source region and a respective doped raised drain region adjacent each of said front gate structure of said nonvolatile memory cell and said gate structure of said field effect transistor; and
diffusing dopants from said doped raised source and drain regions into portions of said semiconductor layer below said doped raised source and drain regions.

15. The method of claim 14, wherein said semiconductor structure is a fully depleted semiconductor-on-insulator structure.

16. (canceled)

17. The method of claim 15, wherein said first ion implantation process is performed at a temperature in a range from room temperature to about 450° C.

18. The method of claim 17, wherein said first ions include ions of germanium, and wherein said annealing process is a furnace annealing process that is performed at a temperature in a range from about 900-1100° C. and an annealing time after temperature ramp in a range from about 30-90 minutes.

19. The method of claim 18, wherein an ion dose of said first ion implantation process is in a range from about 2·10¹⁵ ions/cm² to about 5·10¹⁵ ions/cm² and wherein an ion energy of said first ion implantation process is selected such that a maximum concentration of said implanted first ions is obtained approximately at a center of a vertical thickness of said buried insulation layer.

20. The method of claim 19, wherein said formation of said trench isolation structure comprises forming one or more trenches extending through said semiconductor layer and said buried insulation layer and forming an electrically insulating material in said one or more trenches, wherein said annealing process is performed after formation of at least a part of said electrically insulating material, said annealing process densifying said at least a part of said electrically insulating material.
